(19) United States
(12) Patent Application Publication
(10) Pub. No.: US 2014/0014927 A1
(43) Pub. Date: Jan. 16, 2014

(54) ORGANIC LIGHT EMITTING DEVICE

(71) Applicants: Mi-Kyung Kim, Yongin-City (KR); Kwan-Hee Lee, Yongin-City (KR); Mie-Hwa Park, Yongin-City (KR)

(72) Inventors: Mi-Kyung Kim, Yongin-City (KR); Kwan-Hee Lee, Yongin-City (KR); Mie-Hwa Park, Yongin-City (KR)

(21) Appl. No.: 13/937,141

(22) Filed: Jul. 8, 2013

(30) Foreign Application Priority Data
Jul. 10, 2012 (KR) 10-2012-0075267

(51) Int. Cl. H01L 51/00; H01L 51/50

(52) U.S. Cl. CPC H01L 51/0067; H01L 51/0072; H01L 51/5072
USPC 257/40

(57) ABSTRACT

An organic light emitting device including a first electrode, a second electrode facing the first electrode, and an organic layer between the first electrode and the second electrode, wherein the organic layer includes an electron transport layer (ETL), and the electron transport layer (ETL) includes a compound represented by the following Chemical Formula 1 and an alkali metal complex.

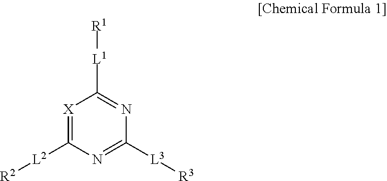

In the above chemical formula,
X, L¹, L² and L³, R¹, R², and R³ are the same as defined in the detailed description.

### CROSS-REFERENCE TO RELATED APPLICATION

This application claims priority to and the benefit of Korean Patent Application No. 10-2012-0075267, filed in the Korean Intellectual Property Office on Jul. 10, 2012, the entire content of which is incorporated herein by reference.

### BACKGROUND

1. Field

An organic light emitting device is disclosed.

2. Description of the Related Art

Since an organic light emitting device has light emitting characteristics and does not require a separate light source unlike a liquid crystal display (LCD), the thickness and the weight of the organic light emitting device may be reduced. Also, since an organic light emitting device exhibits high definition characteristics such as low power consumption, high luminance and high reaction speed, and the like, it has been spotlighted as the next generation display device for portable electronic devices.

An organic light emitting device includes a plurality of organic light emitting elements having a hole injection electrode, an organic emission layer, and an electron implant electrode. In the organic emission layer, light emission is achieved by the energy generated when exitons, produced by combination of electrons and holes, drop from the exited state to the ground state, and the organic light emitting device forms an image therewith.

### SUMMARY

An aspect of an embodiment of the present invention is directed towards an organic light emitting device having high efficiency and long life-span characteristics.

According to one embodiment, an organic light emitting device includes a first electrode, a second electrode facing the first electrode, and an organic layer positioned between the first electrode and the second electrode, wherein the organic layer includes an electron transport layer (ETL), and the electron transport layer (ETL) includes a compound represented by the following Chemical Formula 1 and an alkali metal complex.

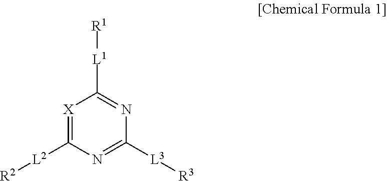

In Chemical Formula 1,

X is carbon or nitrogen,

L¹, L², and L³ are each independently a single bond, or a substituted or unsubstituted C5 to C30 arylene group, and

R¹, R², and R³ are each independently a substituted or unsubstituted C5 to C30 aryl group, or a substituted or unsubstituted C2 to C30 heteroaryl group.

The electron transport layer (ETL) may include the compound represented by Chemical Formula 1 and the alkali metal complex in a weight ratio from about 8:2 to about 2:8.

The electron transport layer (ETL) may be a monolayer or a plurality of layers.

When the electron transport layer (ETL) is a plurality of layers, the electron transport layer (ETL) may include one layer including the compound represented by Chemical Formula 1 and the alkali metal complex, and at least one layer including one selected from the compound represented by Chemical Formula 1, an alkali metal complex, and a combination thereof.

The compound represented by Chemical Formula 1 may include one selected from a compound represented by Chemical Formula 2, a compound represented by Chemical Formula 3, and a combination thereof.

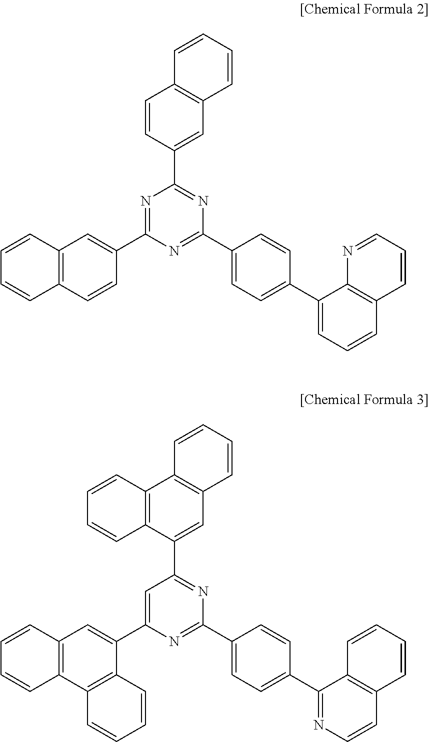 [SMILES: c1ccc2cc(-c3nc(-c4ccc(-c5cccc6cccnc56)cc4)nc(-c4ccc5ccccc5c4)n3)ccc2c1 ; c1ccc2c(-c3ccc(-c4nc(-c5cc6ccccc6c6ccccc56)cc(-c5cc6ccccc6c6ccccc56)n4)cc3)nccc2c1]

In the compound represented by Chemical Formula 1, when at least one of R¹, R², and R³ is a heteroaryl group, a hetero atom of the heteroaryl group may not be directly linked to L¹, L², and L³.

The alkali metal complex may be an oxide, fluoride, quinolate, or acetoacetate of the alkaline metal.

The alkali metal complex may include at least one selected from LiF, NaF, NaCl, CsF, Li₂O, lithium quinolate, sodium quinolate, and a combination thereof.

In an exemplary embodiment of the invention, the compound represented by Chemical Formula 1 may include at least one selected from a compound represented by Chemical Formula 2, a compound represented by Chemical Formula 3, and a combination thereof, and the alkali metal complex may include at least one selected from a compound represented by Chemical Formula 4, a compound represented by Chemical Formula 5, and a combination thereof.

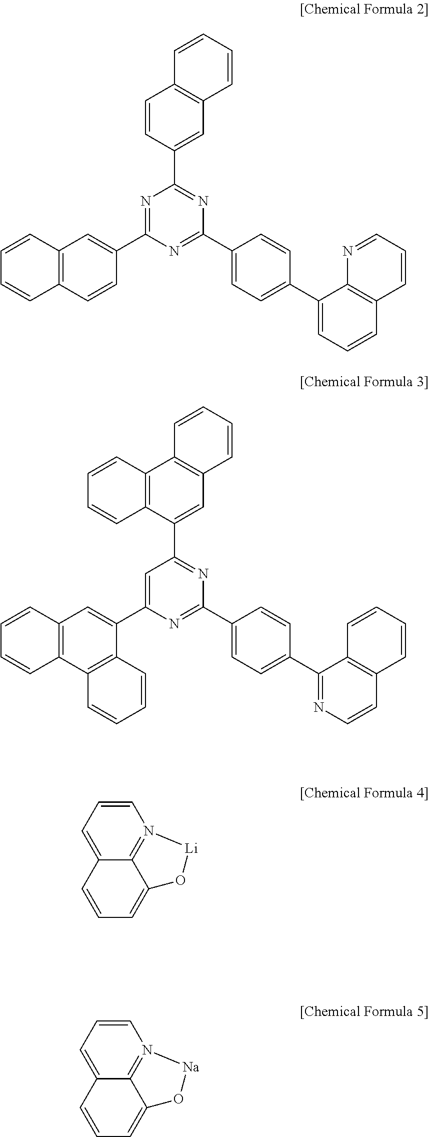

The organic layer may further include at least one selected from a hole injection layer (HIL), a hole transport layer (HTL), an electron blocking layer, an emission layer, a hole blocking layer, an electron injection layer (EIL), besides the above-described electron transport layer (ETL).

### BRIEF DESCRIPTION OF THE DRAWINGS

FIG. 1 schematically shows the cross-section of an organic light emitting device according to one or more embodiments of the invention.

FIG. 2 schematically shows the cross-section of an organic light emitting device according to one or more embodiments of the invention.

FIG. 3 is a voltage-current density graph of the organic light emitting devices according to Example 1 and Comparative Example 1, according to one or more embodiments of the invention.

FIG. 4 is a graph of luminance vs. Time, which shows life-span characteristics of the organic light emitting devices according to Example 1 and Comparative Example 1, according to one or more embodiments of the invention.

### DETAILED DESCRIPTION

Hereinafter, organic light emitting devices according to embodiments are described. The embodiments will be described so that a person of an ordinary skill in the art may understand the spirit of the present invention, but the present invention is not limited thereto. The embodiments may be embodied in many different forms within the spirit and scope of the present invention.

As used herein, when a definition is not otherwise provided, the term “substituted” may refer to one substituted with a C1 to C30 alkyl group; a C1 to C10 alkylsilyl group; a C3 to C30 cycloalkyl group; a C6 to C30 aryl group; a C2 to C30 heteroaryl group; a C1 to C10 alkoxy group; a fluoro group, a C1 to C10 trifluoroalkyl group such as a trifluoromethyl group and the like; or a cyano group.

As used herein, when a definition is not otherwise provided, the term “hetero” may refer to 1 to 3 heteroatoms selected from N, O, S, and P, and remaining carbon in one compound or substituent.

As used herein, when a definition is not otherwise provided, the term “combination thereof” may refer to at least two substituents bound to each other by a linking group, or at least two substituents condensed to each other.

As used herein, when a definition is not otherwise provided, the term “alkyl group” may refer to a “saturated alkyl group” without an alkene group or an alkyne group, or an “unsaturated alkyl group” including at least one of an alkenyl group or an alkynyl group. The term “alkenyl group” may refer to a substituent in which at least two carbon atoms are bound with at least one carbon-carbon double bond, and the term “alkynyl group” refers to a substituent in which at least two carbon atoms are bound with at least one carbon-carbon triple bond. The alkyl group may be a branched, linear, or cyclic alkyl group.

The alkyl group may be a C1 to C20 alkyl group, and more specifically a C1 to C6 alkyl group, a C7 to C10 alkyl group, or a C11 to C20 alkyl group, but is not limited thereto.

For example, a C1-C4 alkyl may have 1 to 4 carbon atoms, and may be selected from methyl, ethyl, propyl, iso-propyl, n-butyl, iso-butyl, sec-butyl, and t-butyl.

Examples of the alkyl group include a methyl group, an ethyl group, a propyl group, an isopropyl group, a butyl group, an isobutyl group, a t-butyl group, a pentyl group, a hexyl group, an ethenyl group, a propenyl group, a butenyl group, a cyclopropyl group, a cyclobutyl group, a cyclopentyl group, a cyclohexyl group, and the like.

The term “aromatic group” may refer to a substituent including a cyclic structure where all elements have p-orbitals which form conjugation. An aryl group and a heteroaryl group may be exemplified.

The term “aryl group” may refer to a monocyclic or fused ring-containing polycyclic (i.e., rings sharing adjacent pairs of carbon atoms) groups.

The “heteroaryl group” may refer to one including 1 to 3 heteroatoms selected from N, O, S, or P in an aryl group, and remaining carbons. When the heteroaryl group is a fused ring, each ring may include 1 to 3 heteroatoms.

As used herein, the term “and/or” may refer to at least one of the listed constituent elements. As used herein, constituent elements and/or portions may be depicted using the words “first”, “second”, and the like, which are used for definite description.

As used herein, when a definition is not otherwise provided, it should be understood that when one constituent element is referred to as being “on” another constituent element, it may be directly on the other element or intervening elements may also be present.

In the drawings, the thicknesses and/or relative thicknesses of constituent elements may be exaggerated for clarity so that embodiments of the present invention can be definitively described. The terms indicating positions such as “upper” and “under” may be used for definitive description of relative positions, and may not indicate absolute positions of constituent elements.

Hereinafter, organic light emitting devices according to embodiments of the present invention are described with reference to drawings.

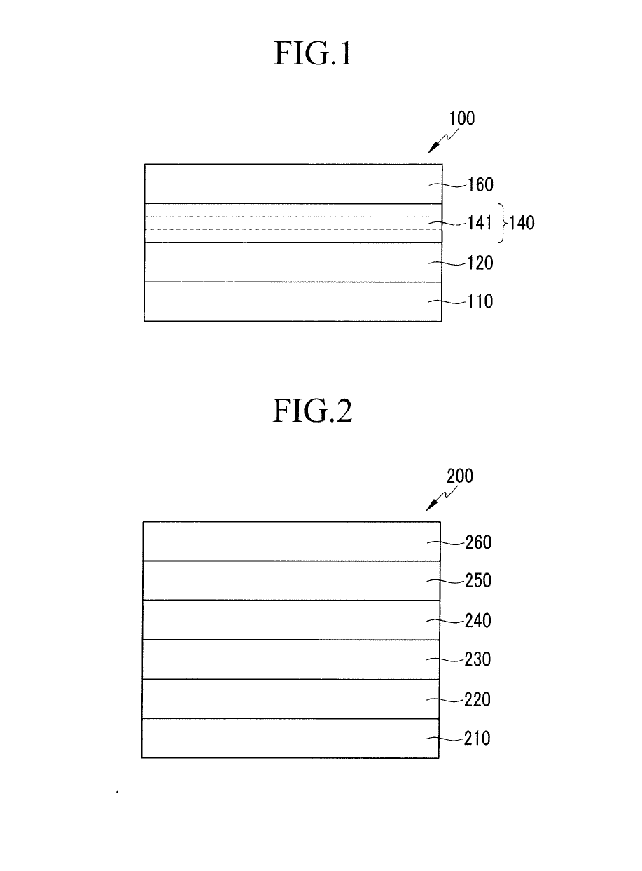

FIG. 1 schematically shows a cross-section of an organic light emitting device according to one or more embodiments of the present invention.

Referring to FIG. 1, an organic light emitting device 100, according to some embodiments, includes a first electrode 120, an organic layer 140 formed on the first electrode 120, and a second electrode 160 formed on the organic layer 140, the organic light emitting device 100 being positioned on a substrate 110.

The substrate 110 may be made of a glass substrate, a silicon wafer, a polymer film, and the like.

One of the first electrode 120 and the second electrode 160 may be an anode and the other may be a cathode. In certain embodiments, the first electrode 120 and the second electrode 160 is a transparent or opaque electrode. For example, in an embodiment of the present invention, the first electrode 120 and the second electrode 160 include one selected from Indium Tin Oxide (ITO), Indium Zinc Oxide (IZO), and a combination thereof, or one selected from aluminum (Al), silver (Ag), and a combination thereof.

In some embodiments, the organic layer 140 includes an electron transport layer (ETL) 141.

In some embodiments, the electron transport layer (ETL) 141 includes a compound represented by Chemical Formula 1 and an alkali metal complex.

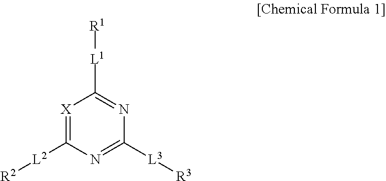

In Chemical Formula 1,

X is carbon or nitrogen,

L¹, L², and L³ are each independently a single bond, or a substituted or unsubstituted C5 to C30 arylene group, and

R¹, R², and R³ are each independently a substituted or unsubstituted C5 to C30 aryl group, or a substituted or unsubstituted C2 to C30 heteroaryl group.

The electron transport layer (ETL) 141, according to some embodiments, includes the compound represented by Chemical Formula 1 and the alkali metal complex in a weight ratio from about 8:2 to about 2:8.

The electron transport layer (ETL) 141 including the compound represented by Chemical Formula 1 and the alkali metal complex, may be formed in a monolayer, or a plurality of layers.

In embodiments, where the electron transport layer (ETL) 141 is a plurality of layers, the electron transport layer (ETL) 141 includes one layer including the compound represented by Chemical Formula 1 and the alkali metal complex, and at least one layer including one selected from the compound represented by Chemical Formula 1, the alkali metal complex, and a combination thereof. That is, in embodiments of the present invention, the plurality of layers includes a random stack of one layer including the compound represented by the above Chemical Formula 1 and the alkali metal complex; and at least one layer including one selected from the compound represented by the above Chemical Formula 1, the alkali metal complex, and a combination thereof.

In embodiments, where the layer including the compound represented by Chemical Formula 1 and the alkali metal complex is one of the plurality of layers, the compound represented by Chemical Formula 1 and the alkali metal complex are included in a weight ratio from about 8:2 to about 2:8.

The compound represented by Chemical Formula 1 may include one selected from a compound represented by Chemical Formula 2, a compound represented by Chemical Formula 3, and a combination thereof.

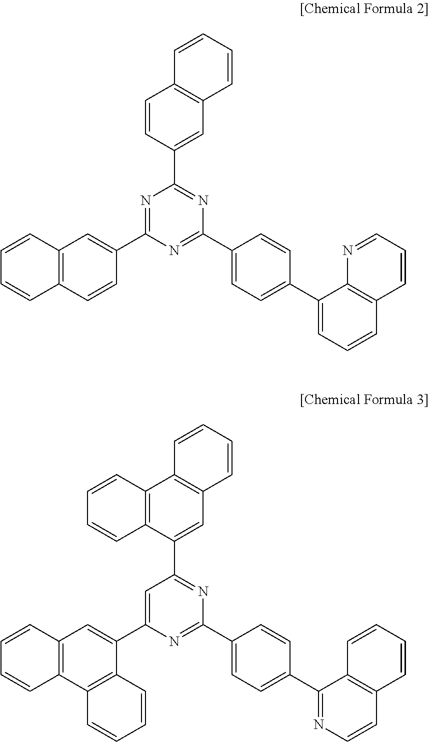 [SMILES: c1ccc2cc(-c3nc(-c4ccc(-c5cccc6cccnc56)cc4)nc(-c4ccc5ccccc5c4)n3)ccc2c1 ; c1ccc2c(-c3ccc(-c4nc(-c5cc6ccccc6c6ccccc56)cc(-c5cc6ccccc6c6ccccc56)n4)cc3)nccc2c1]

Some embodiments provide that in the compound represented by Chemical Formula 1, when at least one of R¹, R², and R³ is a heteroaryl group, a hetero atom of the heteroaryl group is not directly linked to L¹, L², and L³.

The alkali metal complex may be, according to some embodiments, an oxide, fluoride, quinolate, or acetoacetate of the alkaline metal. More specifically, the alkali metal complex may include at least one selected from LiF, NaF, NaCl, CsF, Li₂O, lithium quinolate, sodium quinolate, and a combination thereof.

The alkali metal complex may include, according to some embodiments, at least one selected from a compound represented by Chemical Formula 4, a compound represented by Chemical Formula 5, and a combination thereof.

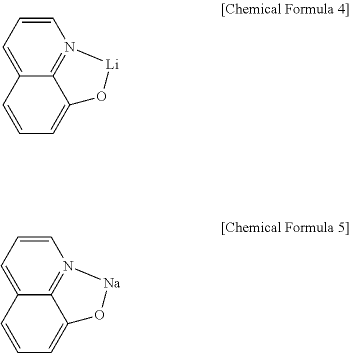

The organic layer 140 may further include an emission layer. In some embodiments, the emission layer is made of an organic material emitting one light among primary colors such as red, green, blue, or the like, or a mixture of an inorganic material with the organic material, for example, a polyfluorene derivative, a (poly)paraphenylenevinylene derivative, a polyphenylene derivative, a polyfluorene derivative, a polyvinylcarbazole, a polythiophene derivative or a compound prepared by doping these polymer materials with a perylene-based pigment, a cumarine-based pigment, a rothermine-based a pigment, rubrene, perylene, 9,10-diphenylanthracene, tetraphenylbutadiene, Nile red, coumarin, quinacridone, and/or the like. In alternative embodiments, an organic light emitting device displays a desirable image by a spacious combination of primary colors emitted by an emission layer therein.

The organic layer 140 may further be an auxiliary layer. In certain embodiments, the auxiliary layer includes at least one of a hole transport layer (HTL), an electron injection layer (EIL), and a hole injection layer (HIL), and the like, besides the above-described electron transport layer (ETL).

The organic light emitting device, according to some embodiments, may realize low efficiency and long life-span characteristics, may be applied to various front-side light emitting, rear-side light emitting, both-sides light emitting, and the like, but is not limited to specific embodiments.

FIG. 2 schematically shows the cross-section of an organic light emitting device according to another embodiment of the present invention.

Referring to FIG. 2, in embodiments of the present invention, the organic light emitting device 200 includes a first electrode 220, a second electrode 260, and an organic emission layer 240 located between the first electrode 220 and the second electrode 260, the organic light emitting device 200 being positioned on a substrate 210. In an embodiment, a lower auxiliary layer 230 is positioned between the first electrode 220 and the organic emission layer 240. In another embodiment, an upper auxiliary layer 250 is positioned between the organic emission layer 240 and the second electrode 260.

In some embodiments, the substrate 210, the first electrode 220, and the second electrode 260 are the same as described in FIG. 1.

The lower auxiliary layer 230, organic emission layer 240, and upper auxiliary layer 250 may form the organic layer 140 of FIG. 1.

In an embodiment, one of the lower auxiliary layer 230 and the upper auxiliary layer 250 includes a hole injection layer (HIL) and/or a hole transport layer (HTL), and the other includes an electron transport layer (ETL) and/or an electron injection layer (EIL). For example, in embodiments, where the first electrode 220 is an anode and the second electrode 250 is a cathode, the lower auxiliary layer 230 includes a hole injection layer (HIL) and/or a hole transport layer (HTL), and the upper auxiliary layer 250 includes an electron injection layer (EIL) and/or an electron transport layer (ETL). Unlike the above, in one or more embodiments where the hole injection layer (HIL) and/or hole transport layer (HTL) are included, the lower auxiliary layer 230 or upper auxiliary layer 250 may be omitted.

In some embodiments, the organic emission layer 240 is the same as described in the emission layer of FIG. 1.

In some embodiments, the electron transport layer (ETL) is the same as explained referring to FIG. 1.

The following examples are describing the present invention in more detail. However, these examples are exemplary, and the present disclosure is not limited thereto.

Manufacture of Organic Light Emitting Device

### Example 1

ITO (an anode) was stacked on a glass substrate and patterned, a compound represented by Chemical Formula a, as a hole injection layer, (HIL) was deposited thereon, a compound represented by Chemical Formula b, as a hole transport layer (HTL), was deposited thereon, an emission layer was formed thereon, and a compound represented by Chemical Formula 2 and lithium quinolate (Liq), as an electron transport layer (ETL), were co-deposited in a weight ratio of 1:1 thereon. Then, MgAg was deposited to form a cathode on the electron transport layer (ETL).

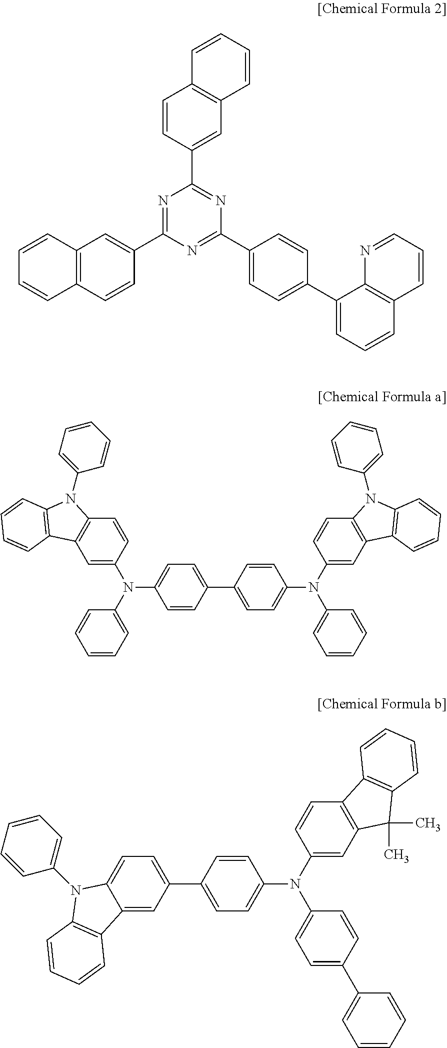 [SMILES: c1ccc2cc(-c3nc(-c4ccc(-c5cccc6cccnc56)cc4)nc(-c4ccc5ccccc5c4)n3)ccc2c1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2ccc(N(c3ccc(-c4ccccc4)cc3)c3ccc(-c4ccc5c(c4)c4ccccc4n5-c4ccccc4)cc3)cc21]

### Example 2

An organic light emitting device was manufactured according to the same method as Example 1 except for co-depositing a compound represented by Chemical Formula 3, instead of the compound represented by Chemical Formula 2, and lithium quinolate (Liq) in a weight ratio of 1:1, as the electron transport layer (ETL).

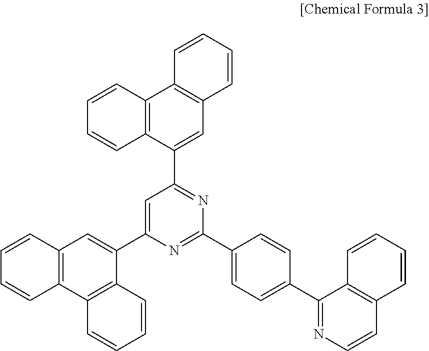 [SMILES: c1ccc2c(-c3ccc(-c4nc(-c5cc6ccccc6c6ccccc56)cc(-c5cc6ccccc6c6ccccc56)n4)cc3)nccc2c1]

### Comparative Example 1

An organic light emitting device was manufactured according to the same method as Example 1 except for co-depositing a compound represented by Chemical Formula 11, instead of the compound represented by Chemical Formula 2, and lithium quinolate (Liq) in a weight ratio of 1:1, as the electron transport layer (ETL).

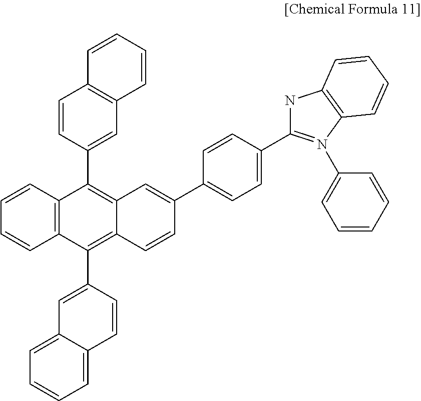

Evaluation 1

Driving voltages, efficiency, CIE color coordinates, and maximum light emitting wavelengths of the organic light emitting devices according to Examples and Comparative Example were measured. The results are provided in the following Table 1.

TABLE 1

| | Driving | | Current | | |
|---|---|---|---|---|---|
| | voltage | Current density | efficiency | Color coordinate | |
| | (V) | (mA/cm²) | (cd/A) | CIE x | CIE y |
| Example 1 | 4.0 | 12.1 | 4.5 | 0.143 | 0.042 |
| Example 2 | 3.6 | 9.5 | 4.0 | 0.141 | 0.043 |
| Comparative | 4.6 | 12.3 | 2.8 | 0.141 | 0.046 |
| Example 1 | | | | | |

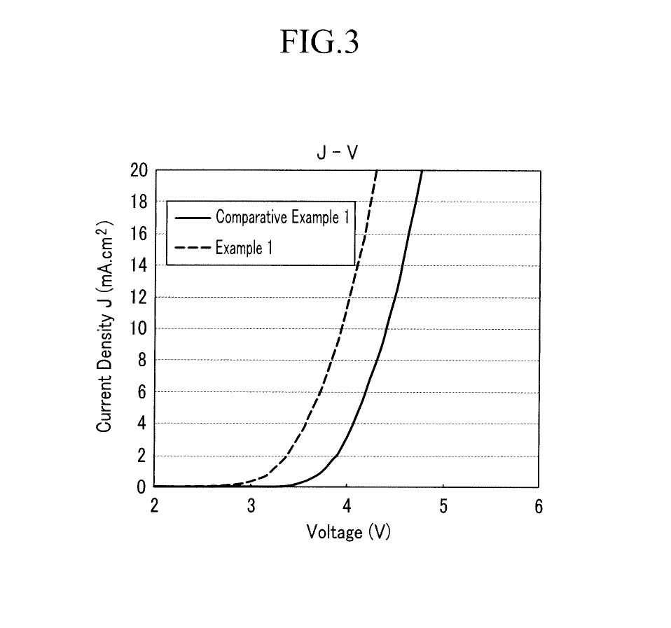

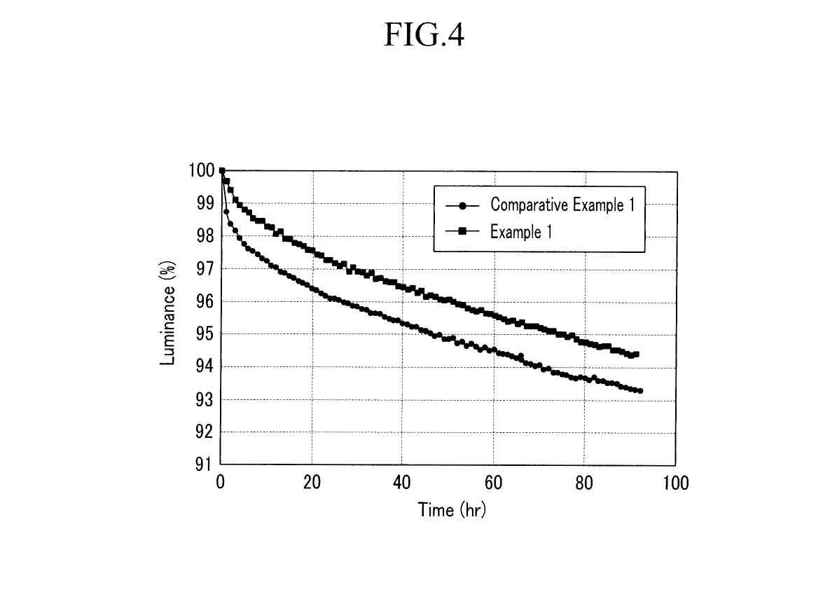

FIG. 3 is a graph showing current density depending on a voltage of the organic light emitting devices according to Example 1 and Comparative Example 1, and FIG. 4 is a graph showing luminance depending on a time of the organic light emitting devices according to Example 1 and Comparative Example 1, to evaluate life-span characteristics.

Referring to FIGS. 3 and 4, the organic light emitting device according to Example 1 showed low driving voltage, high current characteristics, and improved color characteristics and accordingly, improved efficiency and life-span characteristics compared with the organic light emitting device according to Comparative Example 1.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims and equivalents thereof.

What is claimed is:

1. An organic light emitting device, comprising
a first electrode,
a second electrode facing the first electrode, and
an organic layer between the first electrode and
the second electrode,
wherein the organic layer comprises an electron transport layer (ETL), and
wherein the electron transport layer (ETL) comprises a compound represented by the following Chemical Formula 1 and an alkali metal complex: 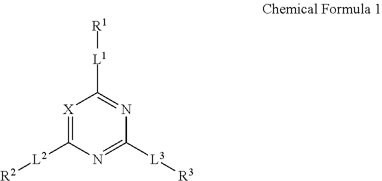
wherein, in the above chemical formula,
X is carbon or nitrogen,
L¹, L², and L³ are each independently a single bond, or a substituted or unsubstituted C5 to C30 arylene group, and
R¹, R², and R³ are each independently a substituted or unsubstituted C5 to C30 aryl group, or a substituted or unsubstituted C2 to C30 heteroaryl group.

2. The organic light emitting device of claim 1, wherein the electron transport layer (ETL) comprises the compound represented by the above Chemical Formula 1 and the alkali metal complex in a weight ratio from about 8:2 to about 2:8.

3. The organic light emitting device of claim 1, wherein the electron transport layer (ETL) is a monolayer or a plurality of layers.

4. The organic light emitting device of claim 3, wherein, the electron transport layer (ETL) is a plurality of layers, and the ETL comprises one layer including the compound represented by the above Chemical Formula 1 and the alkali metal complex, and at least one layer including one selected from the compound represented by the above Chemical Formula 1, an alkali metal complex, and a combination thereof.

5. The organic light emitting device of claim 1, wherein the compound represented by Chemical Formula 1 comprises at least one selected from a compound represented by Chemical Formula 2, a compound represented by Chemical Formula 3, and a combination thereof:

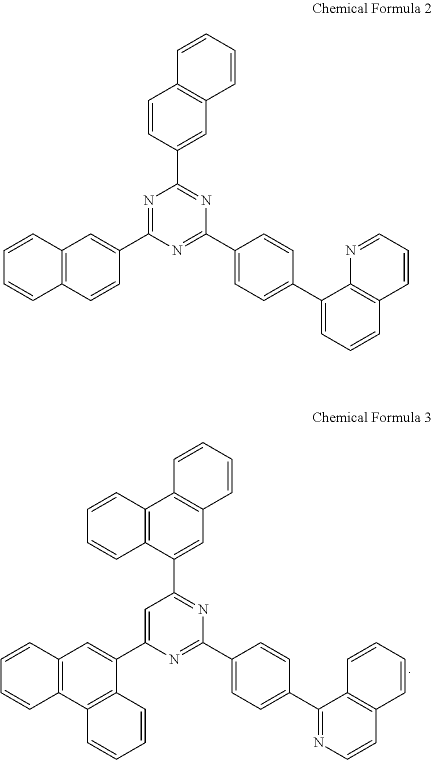 [SMILES: c1ccc2cc(-c3nc(-c4ccc(-c5cccc6cccnc56)cc4)nc(-c4ccc5ccccc5c4)n3)ccc2c1 ; c1ccc2c(-c3ccc(-c4nc(-c5cc6ccccc6c6ccccc56)cc(-c5cc6ccccc6c6ccccc56)n4)cc3)nccc2c1]

6. The organic light emitting device of claim 1, wherein in the compound represented by the above Chemical Formula 1, when at least one of R¹, R², and R³ is a heteroaryl group, a hetero atom of the heteroaryl group is not directly linked to L¹, L², and L³.

7. The organic light emitting device of claim 1, wherein the alkali metal complex comprises an oxide, fluoride, quinolate, or acetoacetate of the alkaline metal.

8. The organic light emitting device of claim 1, wherein the alkali metal complex comprises at least one selected from LiF, NaF, NaCl, CsF, Li₂O, lithium quinolate, sodium quinolate, and a combination thereof.

9. The organic light emitting device of claim 1, wherein the compound represented by Chemical Formula 1 comprises at least one selected from a compound represented by Chemical Formula 2, a compound represented by Chemical Formula 3, and a combination thereof, and
the alkali metal complex comprises at least one selected from a compound represented by Chemical Formula 4, a compound represented by Chemical Formula 5, and a combination thereof:

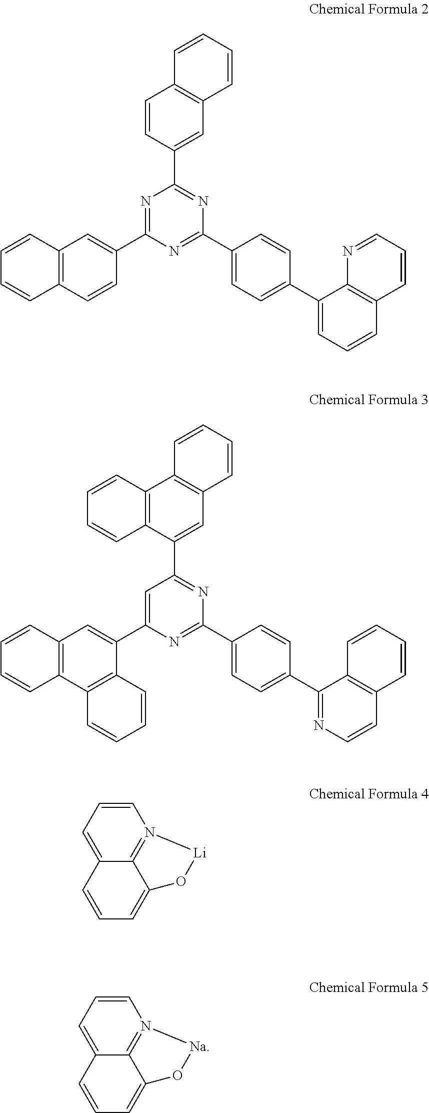

10. The organic light emitting device of claim 1, wherein the organic layer, comprising the electron transport layer (ETL), further comprises at least one selected from a hole injection layer (HIL), a hole transport layer (HTL), an electron blocking layer, an emission layer, a hole blocking layer, and an electron injection layer (EIL).
